(19) United States
(12) Patent Application Publication
(10) Pub. No.: US 2002/0175711 A1
(43) Pub. Date: Nov. 28, 2002

(54) Methodology for improving noise immunity on logic circuits

(76) Inventor: Jason R. Gunderson, Ft. Collins, CO (US)

Correspondence Address: HEWLETT-PACKARD COMPANY, Intellectual Property Administration, P.O. Box 272400, Fort Collins, CO, 80527-2400, US

(21) Appl. No.: 09/864,102

(22) Filed: May 23, 2001

(51) Int. Cl. H03K 19/096

(52) U.S. Cl. 326/98

(57) ABSTRACT

The present invention is directed to a system and method for preserving voltage levels in a logic circuit wherein the system preferably includes a precharge circuit for raising a voltage of first connection points, which are preferably drains, of at least two transistors to a logical high level. Preferably, a plurality of electrically separate interstitial nodes are provided within the logic circuit. Each interstitial node is preferably connected to a second connection point, which is preferably a source, of at least one of the transistors. Preferably, a transistor or other switching mechanism is interposed between each of the interstitial nodes and electrical ground for selectively establishing a connection to ground during an evaluate state or phase of a logic circuit and establishing an open circuit during a precharge state or phase of the logic circuit.

### BACKGROUND

In the field of logic gate design, it is generally desirable to ensure that voltage levels of nodes for indication of the logic state or condition of a gate, such as an OR gate, do not fluctuate outside of an acceptable range. Voltage fluctuation outside of this range may lead to temporary glitches in the apparent logic output of a gate and in more extreme cases to a complete misrepresentation of the output value which is logically appropriate at a particular moment. For example, in the case of an OR gate, where all the inputs are low, the output should represent a logical zero. However, voltage fluctuations in portions of a circuit may operate to alter the logical condition of a portion of this OR gate. This error may then propagate throughout gate circuitry ultimately causing the output of such OR gate to present a logical one or logical “high” value instead of a logical “0” value.

Herein, the acronym FET refers to a field effect transistor. In the following, a DNG FET (a field effect transistor providing a path to electrical ground) is an n-channel device at the bottom of a pull-down stack whose gate is connected to a pre-charge clock. A DNG FET generally prevents a stack with static inputs from being pulled to ground during a pre-charge phase of circuit operation and/or testing. During an evaluation phase of the gate or circuit, it generally operates as a virtual ground.

In a prior approaches to OR gate design, such as that illustrated in FIG. 2, a single interstitial node 202 is generally used for wide (multiple input) dynamic OR gates. In partially depleted SOI (Silicon On Insulator), where the body of a FET is allowed to “float,” such a configuration can lead to significantly higher leakage. To compensate for the increased leakage, PFET (P-Channel junction field-effect transistor) holder 118 generally needs to be much larger when using SOI transistors than when using bulk CMOS (Complementary Metal-Oxide Semiconductor) transistor technology. Employing a larger p-FET holder generally reduces circuit speed (makes evaluation of the circuit slower) and increases power consumption.

During normal operation, circuit 200 will generally be in one of several states. The first of these is generally the pre-charge state. During the pre-charge state, CK (clock signal) 104 is at GND 103 (ground or logic 0), pre-charge FET 128 is on (conducting), and the voltage of pre-charge node “prech” 101 is generally at or very close to supply voltage Vdd 129 which corresponds to the logic value “1” within circuit 200. In addition, during the pre-charge state, DNG FET 203 is generally off (non-conducting). If any of the FETs A-J (identified by reference numerals 108-117) are on, interstitial node 202 will reach a voltage at or very near Vdd-Vt (where Vt is the threshold voltage of FETs (108-117).

As a result of the floating body characteristics inherent to partially depleted SOI transistors, the bodies of FETs A-J will generally be at or near Vdd during the precharge phase. If a FET that was previously on now turns off, the bodies of FETs A-J will remain near Vdd. A case is considered where FET A 108 is initially turned on for an extended period of time. When FET A 108 turns off, there will generally be a coupling event due to gate 124 of FET A 108 transitioning from Vdd 129 to GND 103. Gate-Body Cap (GBCAP) 106 will generally cause the body 125 of FET A 108 to lose some of its charge due to coupling. In addition, Gate-Source Cap (GSCAP) 107 will generally cause interstitial node (into) 202 to lose some of its charge. However, in this wide OR gate structure, the size and capacitance of interstitial node cap (ICAPO) 201 is such that node into 202 does not lose much of its charge, and the bodies of FETs B-J (109-117) remain near Vdd. Also included in FET A 108 are drain 126 and source 127.

During the evaluate state or phase, CK 104 transitions up to Vdd 129. Pre-charge FET 128 is now off, and DNG FET 203 turns on, driving into 202 to GND. Since FETs A-J (108-117) are off, it is desirable to avoid pulling down or reducing the voltage on precharge (prech) node 101. This is because, when FETs A-J (108-117) are all off, precharge node 101 should remain high and thereby cause output 122 to reach a logic 0 level, appropriately indicating that the output 122 of OR gate 200 is low. If precharge node 101 is pulled out of a logic 1 voltage range, the error could propagate through OR gate 200 thereby potentially causing output 122 to incorrectly represent the state of the inputs to OR gate 200. Therefore, when all of FETS A-J (108-117) are off, it is desirable to keep prech node 101 at Vdd, the logic 1 level.

However, with the bodies of FETs B-J (109-117) near Vdd and the sources of FETs B-J (which are connected to into 202) at GND, an inherent parasitic bipolar transistor formed by the drain, body, and source of the SOI transistors is turned on, and charge from precharge node 101 is leaked off. This can result in a glitch on output node 122, or still worse, a complete reversal of that node's proper value. In addition to bi-polar leakage, when the FET bodies are near Vdd, the threshold voltage, Vt, is lower and therefore more susceptible to noise (sub-threshold leakage) on the gates of FETs A-J 108-117

The amount of charge dissipated from precharge node 101 is generally a function of the size of transistors A-J (108-117) and CK 104 proportional to PFET holder 118. With the embodiment shown in FIG. 2, the size of PFET holder 118 may be increased in order to compensate for the depletion of charge from precharge node 101. However, as discussed above, increasing the size of PFET holder 118 generally slows down operation of OR gate 200 and increases power consumption within OR gate or circuit 200.

Accordingly, it is a problem in the art that the body voltages of FET transistors are subject to fluctuation because of the effect of insulated bodies in SOI transistors.

It is a further problem in the art that parasitic bi-polar currents may be generated inside SOI transistors within a logic gate, thereby causing voltage reduction in the drains of such transistors possibly leading to glitches and/or complete reversals of the logic outputs of such gates.

It is a still further problem in the art that addressing the above-described problems of by increasing the size of a PFET holder disposed within a logic gate generally slows down operation of the logic gate and causes an increase in power consumption thereof.

### SUMMARY OF THE INVENTION

The present invention is directed to a system and method for preserving voltage levels in a logic circuit wherein the system preferably includes a precharge circuit for raising a voltage of first connection points, which are preferably drains, of at least two transistors to a logical high level. Preferably, a plurality of electrically separate interstitial nodes are provided within the logic circuit. Each interstitial node is preferably connected to a second connection point, which is preferably a source, of at least one of the transistors. Preferably, a transistor or other switching mechanism is interposed between each of the interstitial nodes and electrical ground for selectively establishing a connection to ground during an evaluate state or phase of a logic circuit and establishing an open circuit during a precharge state or phase of the logic circuit.

### BRIEF DESCRIPTION OF THE DRAWING

FIG. 1 depicts an OR gate having a plurality of interstitial nodes according to a preferred embodiment of the present invention;

FIG. 2 depicts an OR gate having a single interstitial node according to a prior art solution;

FIG. 3 depicts time relationships of various voltage values identified in FIGS. 1 and 2; and

FIG. 4 depicts a selection of capacitance values pertinent to the operation of the circuit of FIG. 1.

### DETAILED DESCRIPTION

Generally, a DNG FET, or transistor operating to pull an interstitial node to ground upon being energized, operates to remove the bulk of any built-up charge in such interstitial node when a clock pulse, or other signal operating to energize a DNG FET, turns on. An important period (hereafter the “transition period”) in distinguishing between the performance of a single interstitial node having a large capacitance and a plurality of interstitial nodes having small capacitances, is that between the transition low of the input to a logic circuit within a logical OR gate, or other logic function, and the transition high of an input to a DNG FET operating to pull to electrical ground an interstitial node connected to the source of at least one logic circuit.

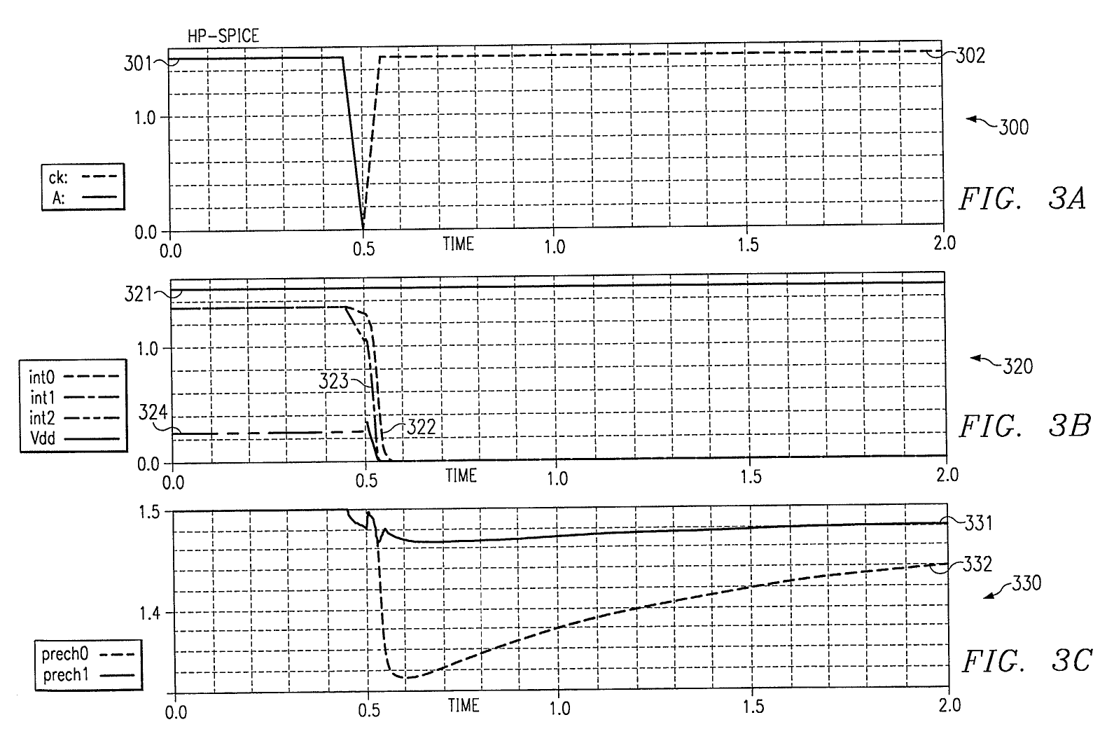

It is during such a transition period that the disparity in charge dissipation rates between the differing configurations of interstitial nodes may be most readily observed. One example of such a disparity is shown in FIG. 3B. Moreover, as may be seen in FIG. 3C, a relatively small disparity in interstitial node voltage during the transition period may cause a much larger voltage disparity between the prech0 and prech1 voltages over an extended period of time. This is because the bi-polar currents generated within FETs A-J 108-117 may be substantially increased due to a small change in the voltage levels of interstitial nodes and of the bodies of the FETs coupled with such interstitial nodes. It may be seen from FIG. 3C that the prech0 voltage is significantly below its “logically” expected voltage even two full nanoseconds after the switching event.

The floating bodies of SOI chips may cause the precharge node voltage depletion to be particularly pronounced because of the much increased tendency toward parasitic bi-polar current in SOI in comparison with bulk CMOS. Thus, employing a plurality of electrically isolated interstitial nodes preferably provides a first benefit of allowing the voltage of a body of a FET whose gate has recently transitioned low to decline more rapidly, thereby greatly diminishing leakage and bi-polar currents within such FET. However, a second benefit of using a plurality of interstitial nodes is that other FETs deployed with an OR gate, or other type of logic circuit, whose gate voltages have been low for a long time (i.e. have not recently transitioned low), may entirely avoid having their body voltages raised to levels which might generate significant leakage and bi-polar currents, thereby benefitting from the electrical isolation of interstitial nodes provided by a preferred embodiment of the present invention.

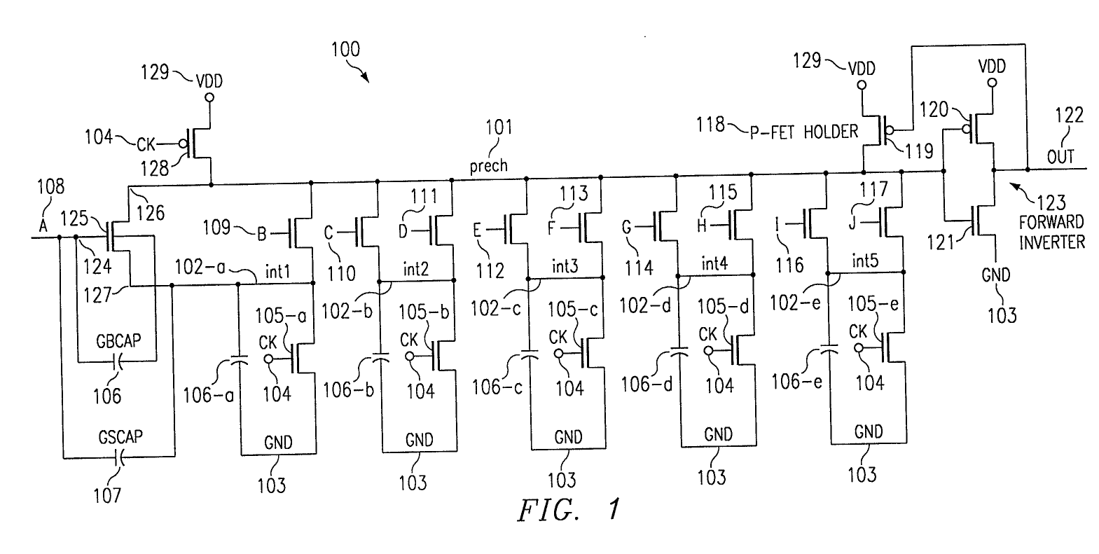

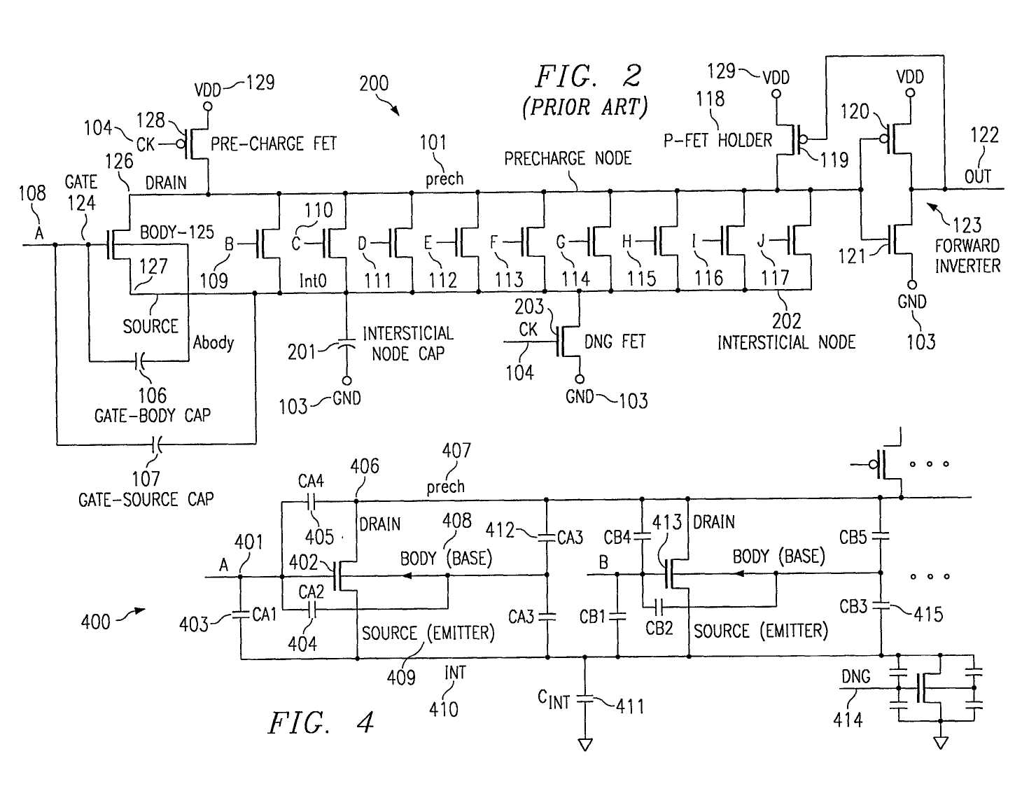

FIG. 1 depicts OR gate 100 having a plurality of interstitial nodes according to a preferred embodiment of the present invention. The embodiment of FIG. 1 helps mitigate the problem of charge buildup of interstitial node 202 (FIG. 2) and the bodies of FETs A-J 109-117 by breaking the interstitial node into multiple components, specifically interstitial nodes 102-a through 102-e. Although the embodiment of FIG. 1 depicts one interstitial node for two FETs each, it will be appreciated that each interstitial node could be connected to fewer or more than two FETs, and all such variations are included in the scope of the present invention.

Generally, the sequence of events and of voltage levels of gate A 124 and clock signal 104 are established in such a way as to test the circuits of FIGS. 1 and 2 under the most demanding circumstances. In this manner, where a circuit succeeds in avoiding output glitches while employing such a demanding scenario, a high level of confidence may be established that OR gate 100 will function correctly under normal operating conditions.

Generally, in the precharge state, clock signal 104 is low and FET A gate 124 is high. These conditions generally operate to maintain precharge node 101 at Vdd and to maintain Vint1 (the voltage of interstitial node 1 102-a) at about Vdd-Vt (where Vt is the threshold voltage of FET A 108). When switching into the evaluate state, these initial conditions present OR gate 100 with a need to dissipate the voltage of int 1 102-a (interstitial node 1) built up during the precharge state so as to avoid generating parasitic bi-polar currents within FET A 108 and possibly triggering an unacceptable decline in voltage in precharge node 101.

In a preferred embodiment, when transitioning from the precharge state to the evaluate state, FET A gate 124 transitions from high to low followed by a transition of clock signal 104 from low to high. A gap in time is provided in between the transition of FET A gate 124 transitioning low and the transition of clock signal 104 from low to high. Preferably, this gap represents the maximum time period, after a transition in a gate input level, such as FET A gate 124, after which OR gate 100 should be able to accurately reflect an instantaneous condition of FETs A-J at output 122. Specifically, once clock signal 104 transitions high, indicating a switch from the precharge phase to the evaluate phase, and where FETs A-J, 108-117 respectively, are all low, precharge node 101 should be high, and output 122 low. Specific time plots will be discussed in greater detail elsewhere herein in connection with FIG. 3.

In a preferred embodiment, the transition from low to high of clock signal 104 disables the connection of precharge node 101 to Vdd 129 via precharge FET 128 and connects int1 (interstitial node 1) 102-a to ground or GND 103 via DNG FET 105-a. Once the transition of clock signal 104 is complete, the connection int1 102-a to ground preferably operates to promptly bring int1 102-a to ground.

In a preferred embodiment, in the time in between FET A gate 124 transitioning low and the transition high of clock signal 104, the design characteristics of OR gate 100 operate to advantageously expedite charge depletion at int1 102-a and thereby operate to prevent undesired voltage depletion at precharge node 101. The mechanisms causing voltage depletion in the OR gate 200 of FIG. 2, such as leakage current and parasitic bi-polar current, are preferably minimized in the embodiment of FIG. 1 because of the deployment of multiple, electrically separate interstitial nodes in place of the single interstitial node 202 in the embodiment of FIG. 1 and because of the attendant reduction in undesired capacitance of the DNG FETs (105-a through 105-e) coupling each such node to ground in comparison with the capacitance of the single DNG FET of the embodiment of FIG. 2.

In a preferred embodiment, the small capacitance of interstitial node capacitor 106-a in comparison with that of interstitial node capacitor 201 (FIG. 2), enables charge stored in capacitor 106-a, and by logical extension at node int1 102-a, to be substantially rapidly depleted through GSCAP 107 (gate source capacitor) to FET A gate 124. Generally, the lower the ratio of the value of the interstitial node capacitance value to the capacitance value of GSCAP 107 to which it is connected, the more rapidly FET A gate 124 may pull int1 1025 a to ground. In going from the embodiment of FIG. 2 to that of FIG. 1, the interstitial node capacitor operating to preserve charge at the interstitial node connected to the source of FET A 108 has declined in value, as indicated above, whereas the value of GSCAP 107 has remained the same. Accordingly, the ratio of interstitial node capacitance to GSCAP has declined, thereby making discharge of int1 102-a through GSCAP 107 to gate 124 more rapid than the discharge of Int0 202 (FIG. 2) to gate 124 in the embodiment of FIG. 2. It will be appreciated that a small change in the voltage value of int1 102-a may have a large effect on the voltage value of precharge node 101.

It will appreciated that interstitial node capacitance is generally an undesired phenomenon arising from various circuit connections and not a capacitor which is specifically designed into a circuit. Generally, a reduction in size and current carrying capacity of a DNG FET, such as DNG FET 105a, operates to reduce the capacitance associated with the interstitial node associated with such DNG FET, such as interstitial node 102-a.

FIG. 3 depicts time relationships of various voltage values identified in FIGS. 1 and 2. Throughout FIG. 3, the quantity expressed on the vertical axes is voltage expressed in units of volts, and the quantity expressed on the horizontal axes is time expressed in nanoseconds. In FIG. 3A, reference numeral 301 points to the graph of the value of gate 124 (hereafter gate A) (FIG. 1) of FET A 108 (FIG. 1), and reference numeral 302 points to a graph of the value of clock signal 104. The quantities depicted in FIG. 3 are exemplary, and it will be appreciated that voltage and time values and relationships therebetween other than those depicted in FIG. 3 could be practiced and remain within the scope of the present invention.

From FIG. 3A, it may be seen that the value of gate A is initially high and begins to decline at T=0.45 nanoseconds. Clock signal 104, represented by dotted line 302, starts low, and begins to rise rapidly beginning at T=0.5 nanoseconds. The time window in between the beginning of the decline in the plot 301 of the value of gate A 124 and the beginning of the rise in the clock signal graph 302, corresponds to a period succeeding the beginning of gate A's decline, after which OR gate 100 is expected to be able to accurately reflect the state of FETs A-J 108-117 at output 122 (FIG. 1).

FIG. 3B depicts the variation with time of Int0 202 with plot 322, of Int1 102-1 with plot 323, and of Int2 102-b with plot 324. Plots Int0 and Int1 represent the voltage value of precharge node 101 when used within the circuits of FIG. 1 and FIG. 2, respectively. A plot 321 of supply voltage Vdd is also shown, which as expected, remains substantially constant with time.

It may be seen that Int0 plot 322 and Int1 plot 323 both start at a voltage level fairly close to that of Vdd. At T=0.45 nanoseconds, both Int0 and Int1 begin to discharge. However, it may be seen that Int1 plot 323 declines more rapidly than Int0 plot 322. This more rapid decline is due to a more favorable (i.e. smaller) ratio of interstitial node capacitance to gate-source capacitance for Int1 than for Int0, as discussed in connection with FIG. 1.

Plot 324 of Int2 102-b is shown starting at a level of about 0.2 volts and declining to zero at T=0.5 nanoseconds. The low initial voltage of Int2 102-b in comparison with Int1 102-a is an advantage of the circuit of FIG. 1 over the unified interstitial node embodiment of FIG. 2 made possible by the allocation of a subset of the FETS 108-117 to each of a plurality of interstitial nodes 102-a to 102-e in the embodiment of FIG. 1. The low initial voltage of Int2 102-b would generally be duplicated for interstitial nodes 102-c through 102-e. The lower voltage of interstitial nodes 102-b through 102-e in comparison with that of Int0 202 (FIG. 2) generally provides the advantage of being able to reduce such voltage to zero more rapidly than is possible with the embodiment of FIG. 2. Thus, for interstitial nodes 102-b through 102-e, the process of lowering the node voltage to zero upon activation of clock signal 104 is benefitted by two factors: a) a lower initial voltage for such nodes than is present in the single interstitial node Int0 202 of FIG. 2 and b) a lower interstitial node capacitance present in capacitors 106-b through 106-e which enables more rapid depletion of any particular interstitial node voltage level through the gate-source capacitances of FETs B-J 109-117 coupled to their respective interstitial nodes, as shown in FIG. 1.

In FIG. 3, prech0 plot 332 corresponds to the voltage value of precharge node 101 when used in conjunction with a single interstitial node Int0 in the embodiment of FIG. 2. Prech1 plot 331 represents the value of precharge node 101 in the circuit of FIG. 1. The rapid decline of the value Int1 323 at T=0.45 nanoseconds, as shown in the graph of FIG. 3B, preferably operates to reduce leakage current and parasitic bi-polar transistor effects in FET A 108, thereby enabling prech1 331 plot to remain with a comfortable range of 1.5 volts which is generally the value of Vdd 129. It may also be seen that the more gradual decline of Int0 plot 322 in FIG. 3B correlates with an abrupt decline of prech0 plot 332 in FIG. 3C. This occurs because a small increase in the voltage of an interstitial node, and by extension of the body voltage of an FET connected to such interstitial node, generally causes a greatly increased amount of leakage current and parasitic bi-polar current in the affected FET. Accordingly, the benefit of the more rapid depletion of the Int1 102-a voltage in comparison to the depletion of Int0202 voltage may be readily observed in viewing the disparity in voltage value reductions and in the voltage recovery time periods of prech1 plot 331 and prech0 plot 332.

While the phenomena displayed in FIG. 3 apply to both bulk CMOS and SOI, the floating body effects of SOI circuits generally operate to amplify the impact of leakage current and parasitic bi-polar effects. Thus, the advantages provided by employing a plurality of electrically isolated interstitial nodes are generally greater in SOI circuits than in bulk CMOS circuits.

FIG. 4 depicts a selection of capacitance values pertinent operation of the circuit of FIG. 1. When the value FET A1 402 gate 401 transitions from a high voltage to a low voltage (Vdd to ground), charge is generally redistributed in circuit 400. If, for example, Int 410 (interstitial node) has a voltage close to Vdd, Cint 411 will generally have a charge equal to Q=CV (where Q is the charge, C is the capacitance of the capacitor, and V is the voltage across the capacitor). Similarly, Ca1 403, Ca3 412, and Cb3 415 will have an initial charge.

Generally, when FET A gate 401 transitions from high to low, charge from node Int 410 (interstitial node) and the bodies of FETs A 402 and B 413 will dissipate to make up for the decrease in potential across Ca1 403. A net effect of this dissipation is that node Int 410 and the bodies of FETs A 402 and B 413 will be at lower voltages, the values of which will be determined by the ratio of the capacitances of CA1 403 to Cint 411.

Generally, where Cint 411 is very large in relation to CA1 403, relatively little charge will leave Cint 411, and the voltage of Int 410 will therefore not decline significantly. However, where the capacitances of Cint 411 and CA1 do not significantly differ, more charge will be redistributed, and the voltage of node Int 410 as well as of the bodies of FETs A 402 and B 413 will be significantly reduced. The voltage levels of Int 410 and of the bodies of FETs A 401 and B 413 is important to the operation of circuit 400 because high voltage values at these locations tend to increase the leakage current and parasitic bi-polar effects for FETs A 402 and B 413.

When DNG FET 414 turns on and Int 410 goes to ground, if the body of FET A 402 is high, the base-emitter voltage of FET A 402 is also high, and there will generally be a large leakage current through FET A 402. When the body voltage of FET A 402 is lower, the base-emitter voltage of FET A 402 will generally also be lower, and the leakage current through FET A 402 is generally lower. Accordingly, breaking up the interstitial node preferably operates to advantageously provide a more favorable (smaller) capacitance ratio between Cint 410 and CA1 403, thereby enabling reduced body voltage and, as a result, lower leakage current in FET A 402.

What is claimed is:

1. Apparatus for preserving voltage levels in a logic circuit, the apparatus comprising:
a precharge circuit for raising a voltage of first connection points of at least two transistors to a logical high level;
at least two electrically separate interstitial nodes, wherein each said interstitial node is connected to a second connection point of at least one of said at least two transistors; and
at least one transistor interposed between each of said at least two interstitial nodes and electrical ground.

2. The apparatus of claim 1 wherein said at least two transistors are connected in parallel.

3. The apparatus of claim 1 wherein each of said electrically separate interstitial nodes is connected to two transistors of said at least two transistors.

4. The apparatus of claim 1 wherein said transistors are Field Effect Transistors (FET).

5. The apparatus of claim 1 wherein said transistors are Silicon on Insulator (SOI) Field Effect Transistors.

6. The apparatus of claim 1 further comprising:
a clock signal operable to selectively activate and deactivate said precharge circuit and said interposed transistor.

7. The apparatus of claim 1 further comprising:
a PFET (p-channel junction field effect transistor) holder disposed between said first connection points of said at least two transistors and a supply voltage source.

8. A method for providing noise immunity, the method comprising the steps of:
coupling first contacts of at least two FETs to a precharge node of a logic circuit;
providing at least two electrically separate ground switches in said logic circuit; and
coupling a second contact of each said FET to a first contact of one of said at least two provided electrically separate ground switches, wherein first contacts of said electrically separate ground switches define electrically separate interstitial nodes.

9. The method of claim 8 wherein the providing step comprises the step of:
providing one said ground switch for every two FETs in said logic circuit.

10. The method of claim 8 wherein said first contacts of said at least two FETs are drains and said second contact of each said FET is a source.

11. The method of claim 8 further comprising the step of:
coupling second contacts of said provided at least two electrically separate ground switches to electrical ground.

12. The method of claim 8 further comprising the step of:
coupling said precharge node to an electrical supply voltage corresponding a logical high value during a precharge phase of said logic circuit.

13. The method of claim 12 further comprising the step of:
coupling said interstitial nodes to ground during an evaluate phase of said logic circuit.

14. The method of claim 11 further comprising the step of:
minimizing a ratio of a capacitance between a first interstitial node and electrical ground and a gate-source capacitance of a FET coupled to said first interstitial node.

15. The method of claim 8 further comprising the step of:
providing expedited dissipation of charge from said interstitial nodes through a gate-source capacitance discharge path of a selected FET upon occurrence of a transition from a logical high voltage to a logical low voltage of a gate of said selected FET.

16. A system for protecting voltage levels in a logic circuit, the system comprising:
means for coupling first contacts of at least two FETs to a precharge node of said logic circuit;
means for electrically separating at least two interstitial nodes of said logic circuit;
means for coupling a second contact of each said FET to a selected one of said electrically separate interstitial nodes; and
means for controllably connecting said interstitial nodes to electrical ground.

17. The system of claim 16 further comprising:
means for maintaining said precharge node at a supply voltage level during a precharge phase of said logic circuit.

18. The system of claim 16 further comprising:
means for dissipating charge in said interstitial nodes through gate-source discharge paths in FETs coupled to said interstitial nodes.

19. The system of claim 16 wherein said controllably connecting means comprises:
means for coupling said interstitial nodes to electrical ground during an evaluate phase of said logic circuit.

20. The system of claim 16 further comprising:
a clock signal for establishing one of a precharge phase and an evaluate phase for said logic circuit.
